(19) United States
(12) Patent Application Publication
(10) Pub. No.: US 2018/0104767 A1
(43) Pub. Date: Apr. 19, 2018

(54) TEXTURIZING A SURFACE WITHOUT BEAD BLAST

(71) Applicant: Applied Materials, Inc., Santa Clara, CA (US)

(72) Inventors: Gang PENG, Fremont, CA (US); David W. GROECHEL, Los Altos Hills, CA (US)

(21) Appl. No.: 15/729,360

(22) Filed: Oct. 10, 2017

Related U.S. Application Data
(60) Provisional application No. 62/408,501, filed on Oct. 14, 2016.

(51) Int. Cl. B23K 26/00; B23K 26/12; H01J 37/32

(52) U.S. Cl. CPC B23K 26/0084; H01J 37/32504; B23K 26/123

(57) ABSTRACT

A method of providing a texture to a surface of a component for use in a semiconductor processing chamber is provided. The method includes directing a beam of photons at the surface of the component and scanning the beam of photons across a first region of the surface of the component to form a plurality of features on the surface within the first region. The features that are formed are depressions, protuberances, or combinations thereof.

### CROSS-REFERENCE TO RELATED APPLICATION

This application claims benefit of U.S. Provisional Patent application Ser. No. 62/408,501 (Attorney Docket 24394USL) filed Oct. 14, 2016, which is incorporated herein by reference.

### BACKGROUND

### Field

Embodiments of the present disclosure generally relate to a method of texturizing a surface of a component for use in a semiconductor processing chamber.

### Description of the Related Art

As integrated circuit devices continue to be fabricated with reduced dimensions, the manufacture of these devices becomes more susceptible to reduced yields due to contamination. Consequently, fabricating integrated circuit devices, particularly those having smaller physical sizes, requires that contamination be controlled to a greater extent than previously considered to be necessary.

Contamination of integrated circuit devices may arise from sources such as undesirable stray particles impinging on a substrate during thin film deposition, etching, or other semiconductor fabrication processes. In general, the manufacturing of the integrated circuit devices includes the use of chambers, including, but not limited to, physical vapor deposition (PVD) sputtering chambers, chemical vapor deposition (CVD) chambers, and plasma etching chambers. During the course of deposition and etch processes, materials often condense from the gas phase onto various internal surfaces of the chamber and surfaces of chamber components disposed within the chamber. When the materials condense from the gas phase, the materials form solid masses that reside on the chamber and component surfaces. This condensed foreign matter accumulates on the surfaces and is prone to detaching or flaking off from the surfaces during or in between a wafer process sequence. This detached foreign matter may impinge upon and contaminate the wafer substrate and devices thereon. Contaminated devices frequently must be discarded, thereby decreasing the manufacturing yield of the process.

In order to prevent detachment of foreign matter that has condensed, the internal surfaces of the chamber and the surfaces of chamber components disposed within the chamber may be provided with a particular surface texture. The surface texture is configured such that the condensed foreign matter that forms on these surfaces has enhanced adhesion to the surface and is less likely to detach and contaminate a wafer substrate. A key parameter of the surface texture is the surface roughness.

One common texturizing process is bead blasting. In a bead blasting process, solid blasting beads are propelled towards the surface to be texturized. One manner in which the solid blasting beads can be propelled towards the surface to be texturized is by pressurized gas. The solid blasting beads are made of a suitable material, for example, aluminum oxide, glass, silica, or hard plastics. Depending upon the desired surface roughness, the blasting beads can be of varying sizes and shapes.

However, it can be difficult to control the uniformity and repeatability of the bead blasting process. Moreover, during the bead blasting process, the surface being texturized may become sharp and jagged such that tips of the surface break off because of the impact of the solid blasting beads, thereby introducing a source of contamination. In addition, the blasting beads may become entrapped or embedded within the surface during the bead blasting process. For example, if the surface being texturized includes a small through-hole of a varying width (for e.g., a gas distribution showerhead), the blasting bead may become entrapped within the through-hole. In such a situation, the blasting bead not only prevents the through-hole from functioning as a gas passageway, for example, but it also introduces a potential source of contamination for a wafer substrate.

An electromagnetic beam can also be used to texturize a chamber surface. Using an electromagnetic beam to texturize a chamber surface may overcome some of the above-identified problems associated with bead blasting. However, the electromagnetic beam must be operated under vacuum to prevent scattering. Scattering can occur when electrons within the electromagnetic beam interact with air or other gas molecules. Consequently, the electromagnetic beam must be operated within a vacuum chamber. The need for a vacuum chamber limits the size of components that can be texturized because the component must be able to fit within the vacuum chamber. Moreover, the capital costs associated with operating an electromagnetic beam are significantly higher than the capital costs associated with bead blasting process. For example, the need for a vacuum chamber increases the costs associated with texturing a surface with an electromagnetic beam.

Therefore, there is a need for an improved texturizing process that overcomes the problems associated with bead blasting while avoiding the capital costs and size constraints associated with the use of an electromagnetic beam.

### SUMMARY

One implementation of the present disclosure relates to a method of providing a texture to a surface of a component for use in a semiconductor processing chamber. The method includes directing a beam of photons through ambient air or nitrogen at the surface of the component; and scanning the beam of photons across a first region of the surface of the component to form a plurality of features on the surface within the first region, wherein the features that are formed are depressions, protuberances, or combinations thereof.

Another implementation of the present disclosure relates to a method of providing a texture to a surface of a component for use in a semiconductor processing chamber. The method includes directing a beam of photons at the surface of the component in an atmosphere having a pressure generally equivalent to atmospheric pressure; and scanning the beam of photons across a first region of the surface of the component to form a plurality of features on the surface within the first region, wherein the features that are formed are depressions, protuberances, or combinations thereof.

Another embodiment of the present disclosure is a component for use in a semiconductor processing chamber. The component includes a plurality of features on a surface within a first region, wherein the features that are formed are depressions, protuberances, or combinations thereof. The features are formed by scanning a beam of photons across the surface of the component.

### BRIEF DESCRIPTION OF THE DRAWINGS

So that the manner in which the above recited features of the present disclosure can be understood in detail, a more particular description of the disclosure, briefly summarized above, may be had by reference to implementations, some of which are illustrated in the appended drawings. It is to be noted, however, that the appended drawings illustrate only exemplary implementations and are therefore not to be considered limiting of its scope.

FIG. 1 illustrates a schematic view of a laser machine and a support system in accordance with the present disclosure.

FIG. 2 illustrates an alternative schematic view of a laser machine and a support system in accordance with the present disclosure.

FIG. 3 illustrates a top view of a gas distribution showerhead, with a region to be texturized marked by boundary lines.

FIG. 4 illustrates a process sequence for a method of operating a laser machine and a support system in accordance with the present disclosure.

FIGS. 5 and 6 illustrate a surface morphology of a repeating random form, the surface morphology being created by a laser machine in accordance with the present disclosure. FIG. 5 illustrates a perspective view showing the surface morphology and FIG. 6 illustrates a top view showing the surface morphology.

FIGS. 7 and 8 illustrate a surface morphology of a repeating wave form, the surface morphology being created by a laser machine in accordance with the present disclosure. FIG. 7 illustrates a perspective view showing the surface morphology and FIG. 8 illustrates top and side views showing the surface morphology.

FIGS. 9 and 10 illustrate a surface morphology of a repeating square form, the surface morphology being created by a laser machine in accordance with the present disclosure. FIG. 9 illustrates a perspective view showing the surface morphology, and FIG. 10 illustrates top and side views showing the surface morphology.

To facilitate understanding, identical reference numerals have been used, where possible, to designate identical elements that are common to the figures. It is contemplated that elements and features of one implementation may be beneficially incorporated in other implementations without further recitation.

The patent or application file contains at least one drawing executed in color. Copies of this patent or patent application publication with color drawing(s) will be provided by the Office upon request and payment of the necessary fee.

### DETAILED DESCRIPTION

Implementations described herein utilize a beam of photons generated by a laser to perform a texturizing process on a surface of a component for use in a semiconductor processing chamber. The beam of photons is directed at the surface of the component and scanned across a region of the surface to form a plurality of features. The features formed on the surface include depressions, protuberances, and/or combinations thereof. The beam of photons may be reduced in intensity, defocused, and/or scanned at a particular travel speed to form a desired surface morphology.

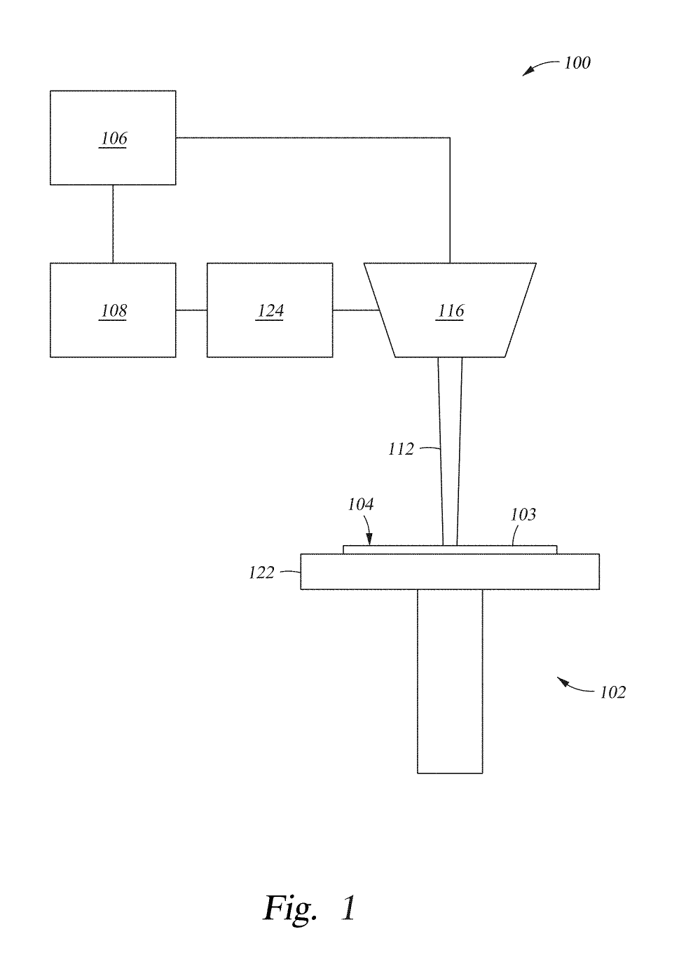

FIG. 1 depicts a schematic view of a laser machine 100 that may be used to texturize a surface 103 of a component 104 and a support system 102. The component 104 may be, for example, a gas distribution showerhead, a chamber wall, or an electrostatic chuck. The laser machine 100 comprises a power supply 106, a controller 108, and a laser device 116. The laser device 116 outputs a beam of photons 112. The controller 108 may comprise a modulator and/or a scanner to modulate and scan the beam of photons 112. The laser machine may further comprise a pulse supply unit to pulse the beam of photons 112. Pulsing the beam of photons 112 can help minimize the amount of heat applied to the surface 103 of the component 104. In addition, pulsing the beam of photons 112 can help reduce problems incurred as a result of the reflectivity of the surface 103 of the component 104. Embodiments disclosed herein may be utilized to texturize the surface 103 of the component 104 to have an arithmetic average of the roughness profile (Ra) of about 60 μin to about 360 μin.

The component 104 may comprise a material such as a metal or metal alloy, a ceramic material, a polymer material, a composite material, or combinations thereof. In one implementation, the component 104 comprises a material selected from the group comprising steel, stainless steel, tantalum, tungsten, titanium, copper, aluminum, nickel, gold, silver, aluminum oxide, aluminum nitride, silicon, silicon nitride, silicon oxide, silicon carbide, sapphire (Al₂O₃), silicon nitride, yttria, yttrium oxide, and combinations thereof. In one implementation, the component 104 comprises metal alloys such as austenitic-type stainless steels, iron-nickel-chromium alloys (e.g., Inconel™ alloys), nickel-chromium-molybdenum-tungsten alloys (e.g., Hastelloy™), copper zinc alloys, chromium copper alloys (e.g., 5% or 10% Cr with balance Cu), or the like. In another implementation, the component comprises quartz. The component 104 may also comprise polymers such as polyimide (Vespel™), polyetheretherketone (PEEK), polyarylate (Ardel™), and the like. In yet another implementation, the component 104 may comprises a material such as gold, silver, aluminum silicon, germanium, germanium silicon, boron nitride, aluminum oxide, aluminum nitride, silicon, silicon nitride, silicon oxide, silicon carbide, yttria, yttrium oxide, non-polymers, and combinations thereof.

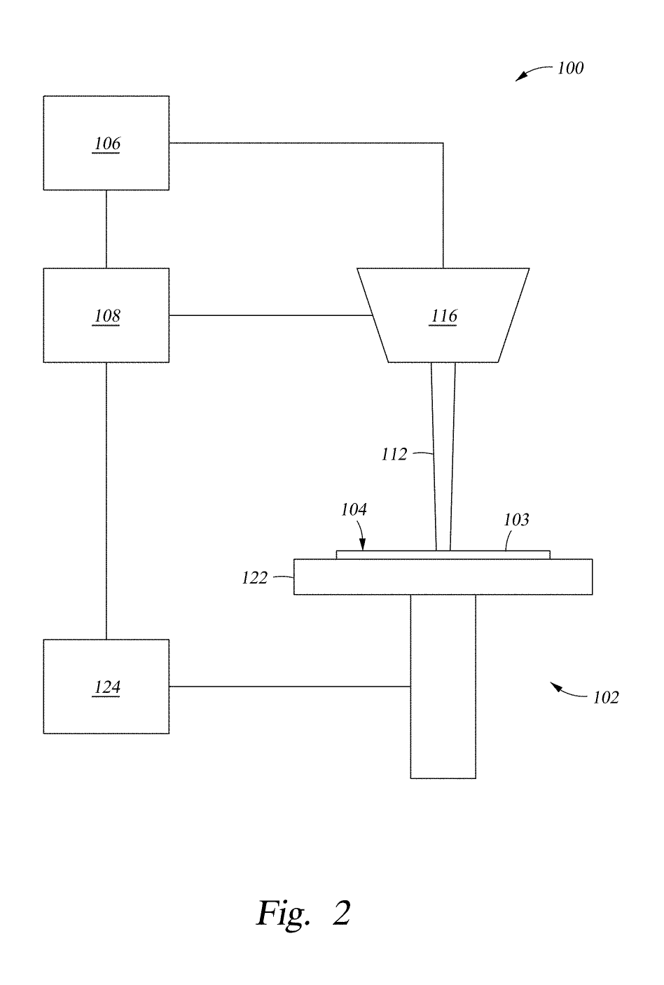

The support system 102 may be positioned downstream of the laser machine 100. The support system 102 comprises a substrate support 122 for supporting component 104. The support system 102 and laser machine 100 are positioned relative to each other such that the beam of photons 112 outputted by the laser device 116 is directed at the surface 103 of the component 104. In one implementation of the present disclosure illustrated in FIG. 1, the laser machine 100 may further comprise an actuating means 124 for adjusting the position of the laser device 116. In such an implementation, the substrate support 122 may remain stationary and the actuating means 124 may adjust the position of the laser device 116, thereby causing the beam of photons 112 outputted by the laser device 116 to be scanned across the surface 103. In an alternative implementation of the present disclosure illustrated in FIG. 2, the support system 102 may comprise the actuating means 124 for moving the substrate support 122. In such an implementation, the laser device 116 may remain stationary and the actuating means 124 may adjust the position of the substrate support 122, thereby causing the beam of photons 112 outputted by the laser device 116 to be scanned across the surface 103. The actuating means 124 for adjusting the position of either the laser device 116 or the substrate support 122 may comprise, for example, an extension arm and/or rotating shaft capable of translational movement and/or rotational movement.

The controller 108 may be connected to the laser device 116 in a manner that enables the controller to control various parameters associated with the beam of photons 112 outputted by the laser device 116. In particular, the controller 108 may be connected to the laser device 116 to control at least the following parameters associated with the beam of photons 112: wavelength, pulse width, repetition rate, travel speed, beam size, and particle size. By being able to control these various parameters associated with the beam of photons 112, the controller 108 is able to dictate the surface morphology formed on the surface 103 of the component 104. It should be understood that “travel speed” incorporates an implementation where the beam of photons 112 is being moved and the component 104 is stationary and an implementation where the beam of photons 112 is stationary and the component is being moved. As shown in FIG. 2, the controller 108 may also be connected to the support system 102 in a manner that enables the controller to control an actuating means 124 connected to the substrate support 122. Alternatively, a secondary controller may be connected to the support system 102 to control an actuating means 124 connected to the substrate support 122.

The controller 108 may be one of any form of general purpose computer processor (CPU) that can be used in an industrial setting. The computer may use any suitable memory, such as random access memory, read only memory, floppy disk drive, hard disk, or any other form of digital storage, local or remote. Various support circuits may be coupled to the CPU for supporting the processor in a conventional manner. Software routines as required may be stored in the memory or executed by a second CPU that is remotely located. The software routine, when executed, transforms the general purpose computer into a specific process computer that controls the operation so that a chamber process is performed. Alternatively, the implementation described herein may be performed in hardware, as an application specific integrated circuit or other type of hardware implementation, or a combination of software or hardware.

The laser machine 100 may have a power output in a range of about 3 W to about 30 W. Alternatively, the laser machine may have a power output in a range of about 1 W to about 150 W. The laser machine 100 may be a commercially available laser machine. An example of a commercially available laser machine that may be in accordance with the present disclosure is IPG YLPP laser of Spectral Physics Quanta-Ray Laser.

The laser machine 100 and the support system 102 do not require a specialized environment to perform the texturizing process because the output of the laser device 116 is a beam of photons 112. Because photons are neutral particles, the beam of photons 112 outputted by the laser device 116 will be able to maintain cohesion when directed at the surface 103 of the component 104. This differs from an electromagnetic beam system in which an electron-beam is used to perform the texturizing process. An electromagnetic beam system typically requires a vacuum environment (e.g., a vacuum chamber). The vacuum environment is necessary to maintain precise control of the electron beam. By lowering the ambient pressure, the electron beam can be controlled and scattering resulting from the interaction of the electrons of the electron beam with air or other gas particles mitigated. The requirement of the vacuum environment imposes physical constraints on the size of component that can be texturized using the electromagnetic beam system, as the component must be able to fit within the vacuum chamber. In addition, the requirement of the vacuum environment increases the complexity of the electromagnetic system because the vacuum chamber must include special equipment (e.g., a pump, sensors, seals). Consequently, electromagnetic beam systems have significantly higher capital costs than that which would be incurred when using the laser machine 100 and the support system 102 discussed in the present disclosure to perform the texturizing process.

Thus, the laser machine 100 and the support system 102 can be used in an ambient air environment in which the air through which the beam of photons 112 passes is approximately 78% nitrogen and approximately 21% oxygen. In some situations, however, it may be desirable to locate the laser machine 100 and the support system 102 within an oxygen-depleted environment. In such a situation, the laser machine 100 and the support system 102 can be positioned within a chamber where nitrogen gas is used in place of ambient air. Because a vacuum is not required, the pressure within the chamber can be maintained at atmospheric pressure. It is to be understood that “atmospheric pressure” may differ from one location to another.

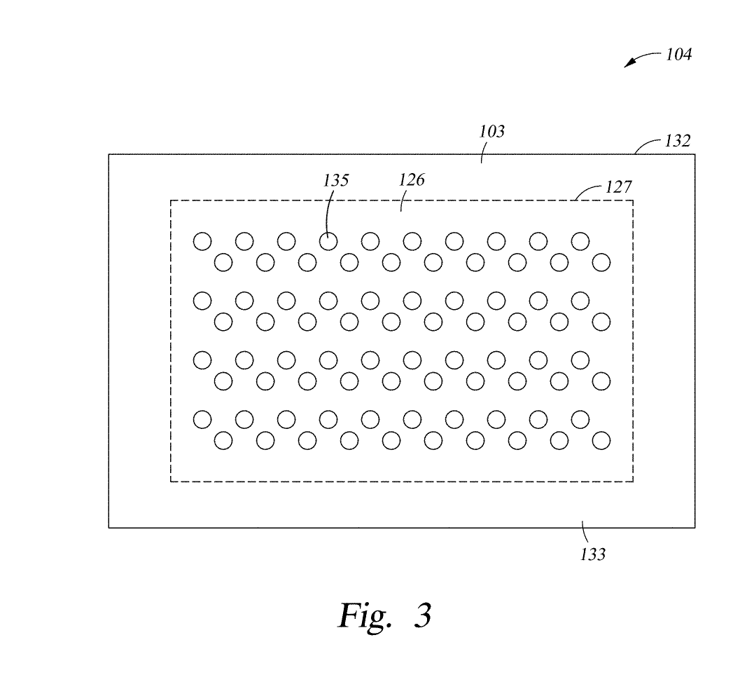

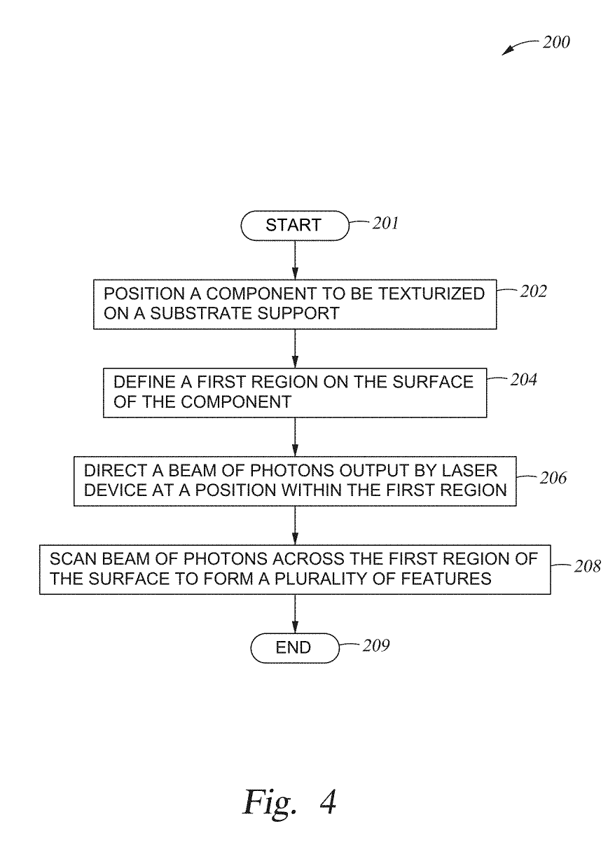

FIG. 4 depicts a process sequence 200, which begins at 201 and ends with 209, for a method of operating the laser machine 100 and the support system 102. At box 202, the component 104 is positioned on the substrate support 122. At box 204, a first region 126 is defined on the surface 103 of the component 104. As illustrated in FIG. 3, in which component 104 is a gas distribution showerhead 133 having a plurality of through-holes 135, the first region 126 has a first outer boundary 127 defining the outer bounds of the first region. The first outer boundary 127 defines a first surface area. A ratio of the first surface area to a second surface area of the component 104 may be at least 0.6. The second surface area of the component 104 is defined by a second outer boundary 132 of the surface 103 being texturized. Thus, the first surface area, which is positioned within the second surface area, may be at least 60% of the second surface area. It is to be understood that the size of the first and second surface areas will vary depending upon the shape and size of the component 104 that is being texturized. Alternatively, the ratio of the first surface area to the second surface area may be greater than 0.7, 0.8, and/or 0.9.

At box 206, the laser machine 100 is powered via power supply 106 such that the laser device 116 outputs a beam of photons 112. As discussed above, controller 108 of the laser machine 100 can vary the parameters associated with the beam of photons 112 depending upon the desired texture on the surface 103. In one implementation, the beam of photons 112 may have a wavelength in a range of between about 345 nm and about 1050 nm. In another implementation, the beam of photons may have a wavelength in the ultra-violet light range (about 10 nm to about 400 nm). In yet another implementation, the beam of photons may have a wavelength in the infrared light range (about 700 nm to about 1 mm). The beam of photons 112 outputted by the laser device 116 is directed towards the surface 103 of the component 104 at a position within the first region 126. The beam of photons 112 may have a beam diameter at the surface 103 of the component 104 in a range of about 7 μm to about 25 μm. Alternatively, the beam of photons 112 may have a beam diameter at the surface 103 of the component 104 in a range of about 2.5 μm to about 100 μm. In one implementation, the working distance traveled by the beam of photons 112 is about 50 millimeters to about 1,000 millimeters. In another implementation, the working distance traveled by the beam of photons 112 is between about 200 millimeters to about 350 millimeters.

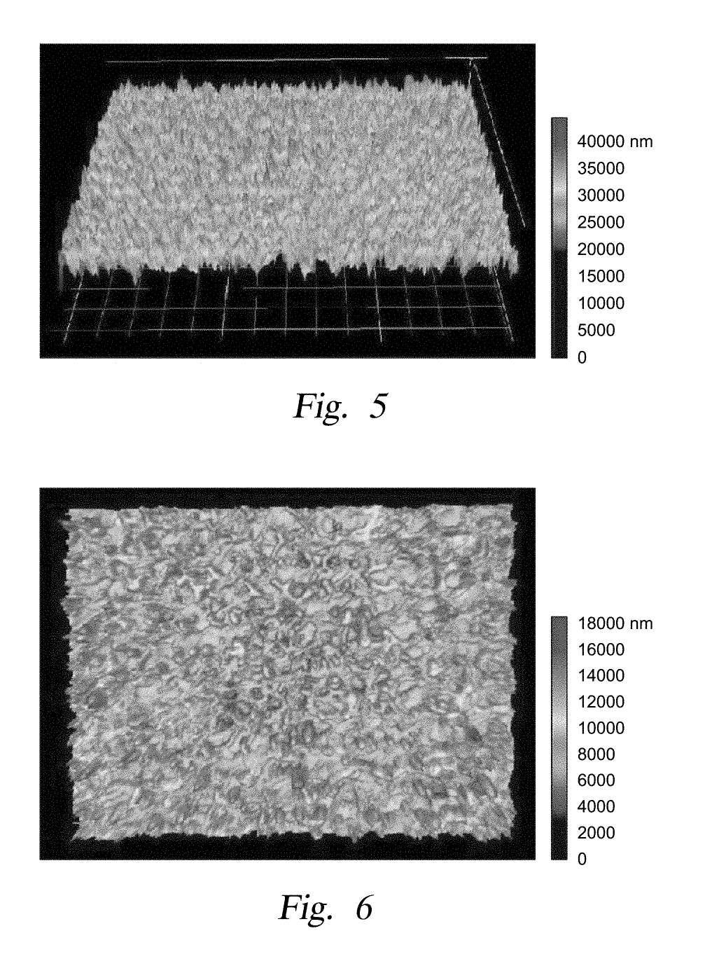

At box 208, the beam of photons 112 is scanned across the first region 126 of the surface 103, thereby forming a plurality of features on the surface. The beam of photons 112 may be scanned across the first region 126 of the surface 103 at a travel speed in a range of between about 0.1 m/s to about 300 m/s. As can be seen in FIGS. 5-10, the features that are formed as a result of the beam of photons 112 being scanned across the first region 126 of the surface 103 include depressions, protuberances, or combinations thereof. The controller 108 can be programmed to vary certain parameters associated with the beam of photons 112 as the beam is being scanned across the first region 126. For example, the controller 108 can pulse the beam of photons 112 while the beam is being scanned across the first region 126. In one implementation, the controller 108 may control the laser device 116 to have a pulse width in a range of between about 0.2 ns to about 100 ns. In one embodiment, the controller 108 may control the laser device 116 to have a pulse width in a range of between about 400 fs to about 200 ns

In another implementation, the controller 108 may control the laser device 116 to have a pulse width in a range of between about 2.5 ns to about 30 ns. The controller 108 may also control the laser device to have a pulse repetition rate in a range of between about 10 KHz to about 2000 KHz in one embodiment. In another embodiment, thee controller 108 may also control the laser device to have a pulse repetition rate in a range of between about 10 KHz to about 3 MHz

In this manner, the laser machine 100 can be used to form an overall surface morphology for the first region.

Depending upon the situation, the laser machine 100 can be used to form three different types of surface morphologies for the first region 126. The first surface morphology is a repeating random form, as shown in FIGS. 5 and 6, wherein the repeating random form generates a combination of protuberances and depressions. It is to be understood that the plurality of protuberances may have, for example, a flat surface and a convex surface. In FIGS. 5 and 6, the highest variation in elevation from the lowest depression to the highest protuberance is in a range of between about 4,000 nm to about 4,500 nm. Because the surface morphology is a repeating random form, the protuberances and depressions do not form a periodic wave.

A repeating form may be achieved by synchronizing pulse frequency and scan rate. As the pulsing laser and substrate move with respect to each other, the laser emits radiation that impacts the substrate surface at a repeating interval, resulting in a repeating form. The exact shape of the repeating form can be adjusted by adjusting the temporal profile of the laser pulses to the scan rate. If a laser pulse with very fast power ramp time, compared to the scan rate, is used, the repeating form will tend toward a substantially rectangular profile because the substrate does not translate far during the ramp-up or ramp-down. If ramp time is very small compared to pulse duration, the repeating form will also tend toward a substantially rectangular profile because the temporal profile of the laser pulse is substantially flat. If scan rate is low compared with pulse duration or ramp time, the repeating form will also tend toward a substantially rectangular profile because the photons delivered by each laser pulse are concentrated in a smaller region of the substrate. Increasing ramp time and/or scan rate relative to pulse duration will result in more rounded or tapered corners of the formed features. The laser pulses themselves can also be modulated by coupling a waveform generator to the laser power supply. In this way, pulses can be generated with more tapered ramp rates, and even sinusoidal temporal profiles. Such measures will result in features that tend toward a wave shape. Feature pitch is determined by the relationship of pulse frequency to scan rate. Thus, feature pitch can be adjusted independently by adjusting pulse frequency, which will be limited at the high end by pulse duration.

An example of the Ra of the repeating random form shown in FIGS. 5 and 6 is about 60 μin when the power output of the laser machine is 30 W, the component 104 is aluminum, and the beam diameter is about 7 μm. It is to be understood that the Ra value will vary depending upon the power output of the laser machine and the various variables associated with beam of photons 112. The repeating random form achieved using the laser machine 100 may have a similar surface morphology and Ra value to that which can be achieved using a bead blasting process, with the exception that use of the laser machine 100 will avoid some of the problems inherent with the bead blasting process. For example, if the component 104 is a gas distribution showerhead 133 (illustrated schematically in FIG. 3), there will be plurality of through-holes 135 that are tapered. As discussed above, the bead blasting process involves blasting a plurality of beads at the surface to be textured at a high velocity. Consequently, there is an inherent lack of control and precision associated with the bead blasting process.

Beads used in the bead blasting process may also become entrapped or embedded within the through-holes 135. Additionally, the beads may strike a corner or edge of the through-holes 135, undesirably altering the profile of the through-holes rather than texturizing surface 103. Using the laser machine 100 to texturize the showerhead with the repeating random form surface morphology will not alter the boundary profile of the through-holes 135 in the showerhead 133 as significantly because of the higher precision that can be achieved through this texturing process. The laser machine 100 may texturize surface 103 within the first region 126 such that repeating random form continually repeats itself within boundaries 127.

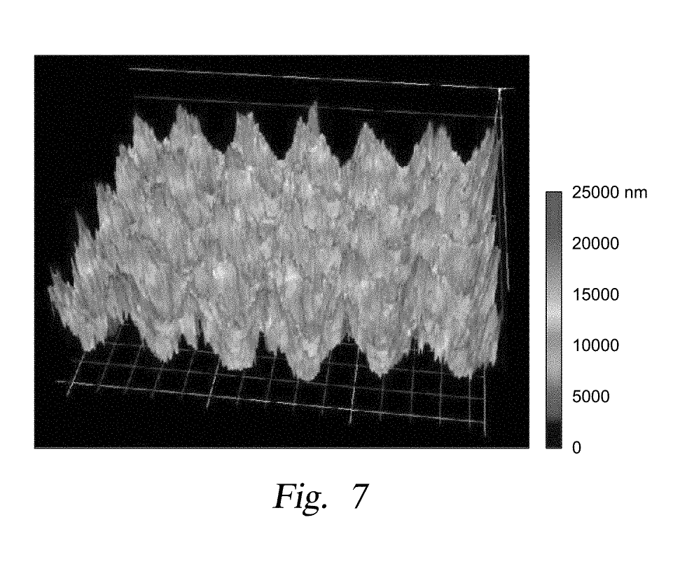

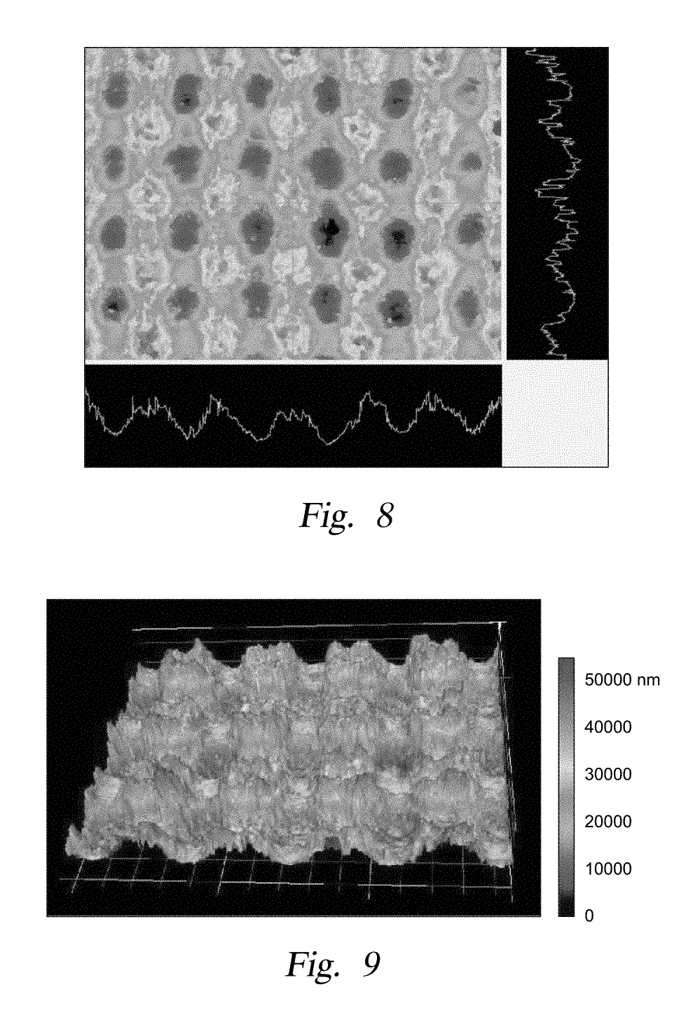

The second surface morphology is a repeating wave form, as shown in FIGS. 6 and 7, wherein the repeating wave form generates a combination of protuberances and depressions. It is to be understood that the plurality of protuberances may have, for example, a generally convex surface. In FIGS. 7 and 8, the highest variation in elevation from the lowest depression to the highest protuberance is in a range of between about 4,000 nm to about 4,500 nm. Because the surface morphology is a repeating wave form, the protuberances and depressions form a periodic profile where each of the plurality of protuberances come to a generally convex, pointed portion. The periodic profile associated with the repeating wave form repeats itself throughout the first region 126 of the surface 103 along both an x-axis of the surface and a y-axis of the surface.

An example of the arithmetic average of the roughness profile (Ra) of the repeating wave form shown in FIGS. 7 and 8 is about 108 μin when the power output of the laser machine is 30 W, the component 104 is aluminum, and the beam diameter is about 7 μm. It is to be understood that the Ra value will vary depending upon the power output of the laser machine and the various variables associated with beam of photons 112. Unlike the repeating random form, the repeating wave form differs from the surface morphology typically achieved using the bead blasting process. The laser machine 100 may texturize surface 103 within the first region 126 such that repeating wave form continually repeats itself within boundaries 127.

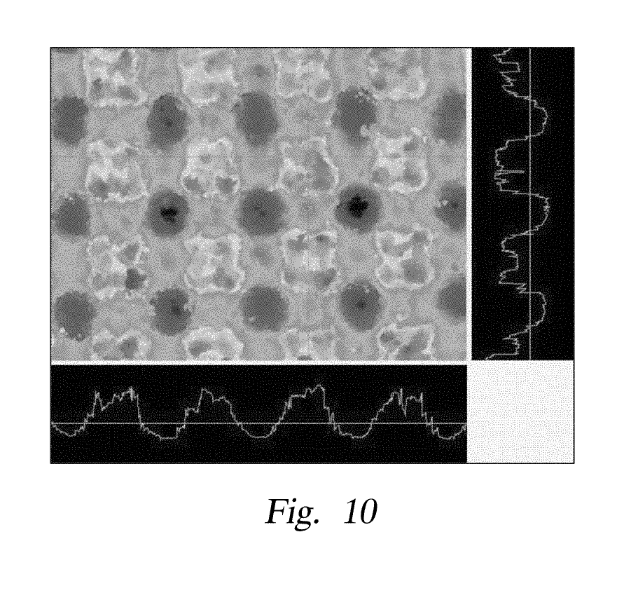

The third surface morphology is a repeating square form, as shown in FIGS. 8 and 9, wherein the repeating square form generates a combination of protuberances and depressions. It is to be understood that the plurality of protuberances may have, for example, a generally flat surface. In FIGS. 9 and 10, the highest variation in elevation from the lowest depression to the highest protuberance is in a range of between about 4,000 nm to about 4,500 nm. Because the surface morphology is a repeating square form, the protuberances and depressions form a periodic profile where each of the plurality of protuberances comes to a generally flat portion. The periodic profile associated with the repeating square form repeats itself throughout the first region 126 of the surface 103 along both an x-axis of the surface and a y-axis of the surface.

An example of the arithmetic average of the roughness profile (Ra) of the repeating square form shown in FIGS. 9 and 10 is about 357 μin when the power output of the laser machine is 30 W, the component 104 is aluminum, and the beam diameter is about 25 μm. It is to be understood that the Ra value will vary depending upon the power output of the laser machine and the various variables associated with beam of photons 112. The repeating square form may be particularly applicable when the component 104 is an electrostatic chuck. As best seen in FIG. 9, the protuberances and depressions within the repeating square form result in a plurality of passageways. The plurality of passageways enable gas to be passed through the passageways underneath a silicon wafer, for example, that is sitting on top of the electrostatic chuck during wafer processing.

A subsequent polishing process may be performed after the texturizing process to help planarize top surfaces of the protuberances, thereby helping the adhesion of the silicon wafer to the electrostatic chuck during wafer processing. The portion of the component 104 not planarized during the polishing process will retain a surface roughness, thereby aiding in the prevention of detachment of foreign matter that has condensed within the plurality of passageways during wafer processing. The laser machine 100 may texturize surface 103 within the first region 126 such that repeating square form continually repeats itself within boundaries 127.

Another benefit associated with the use of the laser machine 100 is that the surface 103 of the component 104 that is being texturized does not have to undergo a precision pre-cleaning process before box 202 of the process. Instead, all that is required is a rough pre-cleaning process to degrease the surface 103 of the component 104. This differs from an electromagnetic beam system, in which a precision pre-cleaning process is generally required because of the highly reactive nature of the electron beam.

Yet another benefit associated with the use of laser machine 100 to texturize the surface 103 of the component 104 is that after box 202, there is not an additional step of pumping down the pressure within a vacuum chamber, as is the case when an electromagnetic beam system is being used. As discussed above, the electromagnetic beam system is operated within a vacuum environment, thereby requiring the pressure of the environment to be pumped down. While laser machine 100 and support system 102 may be positioned within a chamber for the purpose of creating an oxygen-depleted environment, the environment pressure does not have to be pumped down. Because this pumping down step is eliminated, the time required to texturize the surface 103 of component 104 with the laser machine 100 is less than the time required to texturize the surface of the component with an electron beam. This helps increase the throughput associated with texturizing the surface of components with the laser machine 100 as compared to texturizing the surface of components using an electromagnetic beam system. The throughput associated with the laser machine 100 is also greater than the throughput associated with using an electromagnetic beam system because the travel speed at which an electron beam can be scanned across a surface to form a plurality of features is significantly less than the travel speed at which the beam of photons 112 can be scanned across the surface. For example, the travel speed of an electron beam is in a range of between about 0.02 M/s to a range of about 0.03 M/s when texturizing a surface. As discussed above, the travel speed of the beam of photons 112 has a range of between about 0.1 M/s to about 300 M/s when texturizing a surface.

Another benefit associated with texturizing the surface 103 of the component 104 utilizing the beam of photons 112 outputted by the laser device 116 is that it may create a cleaner process than using, for example, bead blasting or an electron beam. Depending upon the wavelength of the beam of photons 112, the material of the surface 103 on which the beam of photons is directed may receive primarily thermal energy to modify the surface. The thermal energy melts the surface 103 of the component 104 at the location on which the beam of photons is directed, thereby creating a slag that, when re-solidified, creates either a depression or protuberance. Because kinetic energy associated with the slag can be minimalized, the slag is less likely to be knocked from the remaining surface 103 and redeposited at some other location. This reduces the amount of re-deposition that might otherwise occur. Conversely, when using an electromagnetic beam system, the component being texturized is often embedded with electrons that interact with the electron beam, creating significant energy that results in at least some of the slag being knocked from the remaining surface and thereby increasing the likelihood of re-deposition. Consequently, texturizing a surface with the beam of photons 112 may result in a cleaner process than texturizing a surface with an electron beam.

It is to be noted that the beam of photons 112 delivered to the surface 103 of the component 104 by the laser device 116 is not intended to cause significant or gross distortion (e.g., melting, warping, cracking, etc.) of the component 104. Significant or gross distortion of the component 104 can be generally defined as a state where the component 104 is not able to be used for its intended purpose due to the application of the texturizing process.

While the foregoing is directed to implementation of the present disclosure, other and further implementation of the disclosure may be devised without departing from the basic scope thereof, and the scope thereof is determined by the claims that follow.

What is claimed is:

1. A method of providing a texture to a surface of a component for use in a semiconductor processing chamber, comprising:
directing a beam of photons through ambient air or nitrogen to the surface of the component; and
scanning the beam of photons across a first region of the surface of the component to form a plurality of features on the surface within the first region, wherein the features that are formed are depressions, protuberances, or combinations thereof.

2. The method of claim 1, wherein the first region has a first outer boundary defining a first area and the surface of the component has a second outer boundary defining a second area, a ratio of the first area to the second area being greater than 0.6.

3. The method of claim 2, wherein the ratio of the first area to the second area is greater than 0.7.

4. The method of claim 3, wherein the ratio of the first area to the second area is greater than 0.8.

5. The method of claim 4, wherein the ratio of the first area to the second area is greater than 0.9.

6. The method of claim 2, wherein the features within the first region form a surface morphology.

7. The method of claim 6, wherein the surface morphology is of a repeating random form.

8. The method of claim 6, wherein the surface morphology is of a repeating wave form.

9. The method of claim 6, wherein the surface morphology is of a repeating square form.

10. The method of claim 9, wherein the component is an electrostatic chuck.

11. The method of claim 1, wherein the beam of photons maintains a beam diameter at the surface in a range of about 7 μm to about 25 μm while the beam of photons is scanning across the first region of the surface of the component.

12. The method of claim 1, wherein the beam of photons has a wavelength in a range between about 345 nm and about 1050 nm.

13. The method of claim 1, wherein the method further comprises pulsing the beam of photons while scanning the beam of photons across the first region.

14. A method of providing a texture to a surface of a component for use in a semiconductor processing chamber, comprising:
directing a beam of photons at the surface of the component in an atmosphere having a pressure generally equivalent to atmospheric pressure; and
scanning the beam of photons across a first region of the surface of the component to form a plurality of features on the surface within the first region, wherein the features that are formed are depressions, protuberances, or combinations thereof.

15. The method of claim 14, wherein the beam of photons maintains a beam diameter at the surface in a range of about 7 μm to about 25 μm while the beam of photons is scanning across the first region of the surface of the component.

16. A component for use in a semiconductor processing chamber, the component comprising:
a plurality of features on a surface within a first region, wherein the features that are formed are depressions, protuberances, or combinations thereof, wherein the features are formed by scanning a beam of photons through ambient air across the surface of the component.

17. The component of claim 16, wherein the first region has a surface morphology.

18. The component of claim 17, wherein the surface morphology is of a repeating random form.

19. The component of claim 17, wherein the surface morphology is of a repeating wave form.

20. The component of claim 17, wherein the surface morphology is of a repeating square form.
